(19) United States
(12) Patent Application Publication
(10) Pub. No.: US 2026/0344247 A1
(43) Pub. Date: Oct. 29, 2026

(54) DISPLAY DEVICE, METHOD OF MANUFACTURING SAME, AND ELECTRONIC DEVICE INCLUDING SAME

(71) Applicant: Samsung Display Co., Ltd., Yongin-si (KR)

(72) Inventors: Changsuk LEE, Yongin-si (KR); Daewon CHOI, Yongin-si (KR)

(73) Assignee: Samsung Display Co., Ltd., Yongin-si (KR)

(21) Appl. No.: 19/633,047

(22) Filed: Mar. 30, 2026

(30) Foreign Application Priority Data
Apr. 25, 2025 (KR) 10-2025-0054445

(51) Int. Cl. H10K 59/80; H10K 59/12; H10K 59/124

(52) U.S. Cl. CPC H10K 59/80515; H10K 59/1201; H10K 59/124; H10K 59/80521

(57) ABSTRACT

A display device includes a substrate, a first electrode on the substrate, a second electrode facing the first electrode and an intermediate layer between the first electrode and the second electrode and including an organic emission layer. The first electrode includes a plurality of protruding portions and one or more valley portions adjacent to the plurality of protruding portions, and at least one of the plurality of protruding portions has a groove in a region in an apex region of the at least one of the plurality of protruding portions.

### CROSS-REFERENCE TO RELATED APPLICATION

This application is based on and claims priority under 35 U.S.C. § 119 to Korean Patent Application No. 10-2025-0054445, filed on Apr. 25, 2025, in the Korean Intellectual Property Office, the disclosure of which is incorporated by reference herein in its entirety.

### BACKGROUND

### FIELD

Embodiments of the disclosure relate to a display device, a method of manufacturing the display device, and an electronic device including the display device.

### DESCRIPTION OF RELATED ART

In recent years, display devices have become increasingly versatile. In addition, display devices are becoming thinner and lighter in weight, which is expanding the scope of their use.

As the number of applications for display devices increases and the technology utilizing display devices improves, the image quality characteristics and high-resolution characteristics required for display devices have been increased.

However, as display devices advance to higher resolutions, there are limitations in improving image quality characteristics and precisely controlling optical characteristics.

### SUMMARY

Embodiments of the disclosure provide a display device capable of enhancing image quality characteristics and precisely controlling optical properties, a method of manufacturing a display device, and an electronic device including the display device.

An aspect of the disclosure provides a display device including: a substrate; a first electrode on the substrate; a second electrode facing the first electrode; and an intermediate layer between the first electrode and the second electrode and including an organic emission layer, wherein the first electrode includes a plurality of protruding portions and one or more valley portions adjacent to the plurality of protruding portions, and wherein at least one of the plurality of protruding portions has a groove in an apex region of the at least one of the plurality of protruding portions.

In an embodiment, one or more insulating layers may be between the substrate and the first electrode, and the one or more insulating layers may have shapes corresponding to the valley portions, the plurality of protruding portions, and the groove of the first electrode.

In an embodiment, each of the one or more insulating layers may include an organic material.

In an embodiment, the one or more valley portions may include a plurality of valley portions, and at least one of the plurality of protruding portions is between the plurality of valley portions.

In an embodiment, the one or more valley portions may be around at least one of the plurality of protruding portions.

In an embodiment, the groove may include a plurality of grooves, and the plurality of grooves may be on the plurality of protruding portions, respectively.

In an embodiment, at least one of the plurality of grooves may have a different shape from another of the plurality of grooves.

In an embodiment, each of the plurality of grooves may have a height corresponding to a distance from the substrate, and the at least one of the plurality of grooves may have a different height from at least one other one of the plurality of grooves.

In an embodiment, the plurality of grooves may have a width in a direction intersecting the distance from the substrate, and the at least one of the plurality of grooves may have a different width from at least one other one of the plurality of grooves.

In an embodiment, positions and shape of the plurality of grooves may be irregular.

In an embodiment, each of the plurality of protruding portions may have an inclined surface.

In an embodiment, each of the plurality of protruding portions may have an area tapered toward the groove.

In an embodiment, each of the plurality of protruding portions may have a shape protruding from the substrate, and a lower surface of the groove may have a recessed shape extending toward the substrate.

Another aspect of the disclosure provides a method of manufacturing a display device including: providing a substrate; forming a first electrode on the substrate, the first electrode comprising a plurality of protruding portions and one or more valley portions adjacent to the plurality of protruding portions; forming a second electrode facing the first electrode; and forming an intermediate layer between the first electrode and the second electrode, the intermediate layer comprising an organic emission layer, wherein at least one of the plurality of protruding portions has a groove positioned in an apex region of the at least one of the plurality of protruding portions.

In an embodiment, the method may include forming one or more insulating layer between the substrate and the first electrode, wherein the one or more insulating layers may have shapes corresponding to the one or more valley portions, the plurality of protruding portions, and the groove of the first electrode.

In an embodiment, the forming of the one or more insulating layers may include: forming a plurality of protrusion patterns on the one or more insulating layers by performing a patterning process; and forming grooves in apex regions of the plurality of protrusion patterns on the one or more insulating layers by selectively etching the one or more insulating layers using a masking member as an etch mask.

In an embodiment, the masking member may have a plurality of apertures.

Still another aspect of the disclosure provides an electronic device including: a processor configured to execute one or more applications and to generate image data; and a display device configured to display images based on the image data. The display device includes : a substrate; a first electrode on the substrate; a second electrode facing the first electrode; and an intermediate layer between the first electrode and the second electrode and including an organic emission layer, wherein the first electrode includes a plurality of protruding portions and one or more valley portions adjacent to the plurality of protruding portions, and wherein at least one of the plurality of protruding portions has a groove in an apex region of the at least one of the plurality of protruding portions.

In an embodiment, the electronic device may further include a memory configured to store data information for operating the processor or the display device, and a power module configured to generate power for operating of the electronic device.

In an embodiment, the electronic device may include an image display electronic device, a wearable electronic device, and a vehicle-mounted electronic device.

Other aspects, features, and advantages not mentioned above will become apparent from the following drawings, claims, and detailed description of the disclosure.

### BRIEF DESCRIPTION OF DRAWINGS

The above and other aspects, features, and advantages of certain embodiments of the disclosure will be more apparent from the following description taken in conjunction with the accompanying drawings in which:

FIG. 1 is a schematic plan diagram illustrating a display device according to an embodiment of the disclosure;

FIG. 2 is a schematic block diagram for a pixel of the display device of FIG. 1;

FIG. 3 is a schematic cross-sectional diagram for a pixel of the display device of FIG. 1;

FIG. 4 is a plan diagram for a pixel of the display device of FIG. 1;

FIG. 5 is another plan diagram for a pixel of the display device of FIG. 1;

FIG. 6 is a schematic cross-sectional diagram illustrating a display device according to another embodiment of the disclosure;

FIGS. 7 to 13 are diagrams illustrating a method of manufacturing a display device according to an embodiment of the disclosure;

FIG. 14 is a diagram illustrating an electronic device equipped with a display device according to an embodiment of the disclosure; and

FIG. 15 is a diagram illustrating various examples of the electronic device of FIG. 14.

### DETAILED DESCRIPTION

The disclosure may be embodied in various forms with multiple modifications, and embodiments are illustrated in the drawings and described in detail in the following detailed description. The effects and features of the disclosure, along with methods for achieving them, will become apparent through reference to the embodiments described in detail below with the accompanying drawings. However, the disclosure is not limited to the embodiments disclosed herein and may be implemented in various forms.

In the following embodiments, the terms first, second, and the like are not intended to be limiting, but are used to distinguish one component from another.

In the following embodiments, singular terms shall include plural referents unless the context clearly indicates otherwise.

In the following embodiments, terms such as comprising or having are intended to imply the presence of the features or components described and do not preclude the possibility of the addition of one or more other features or components.

In the following embodiments, when a layer, region, component, etc. is described as being “on” or “above” another part, it includes not only when it is directly on top of another part, but also when it has other layers, regions, components, etc. interposed therebetween.

For illustrative convenience, elements in the drawings may be exaggerated or reduced in scale. The depicted sizes and thicknesses are schematic and do not limit the invention to the illustrated embodiments.

In the following embodiments, the x-axis, y-axis, and z-axis are not limited to, but may be interpreted in a broad sense to include, three axes in a Cartesian coordinate system. For example, the x-axis, y-axis, and z-axis may be orthogonal to each other, but may also refer to different directions that are not orthogonal to each other.

Certain process sequences may be performed in a different order than described when certain embodiments are otherwise feasible. For example, two processes described in succession may be performed substantially simultaneously, or may be performed in the opposite order from that described.

Embodiments of the disclosure will be described in detail with reference to the accompanying drawings, wherein identical or corresponding components are designated by the same drawing numerals, and duplicate descriptions will be omitted.

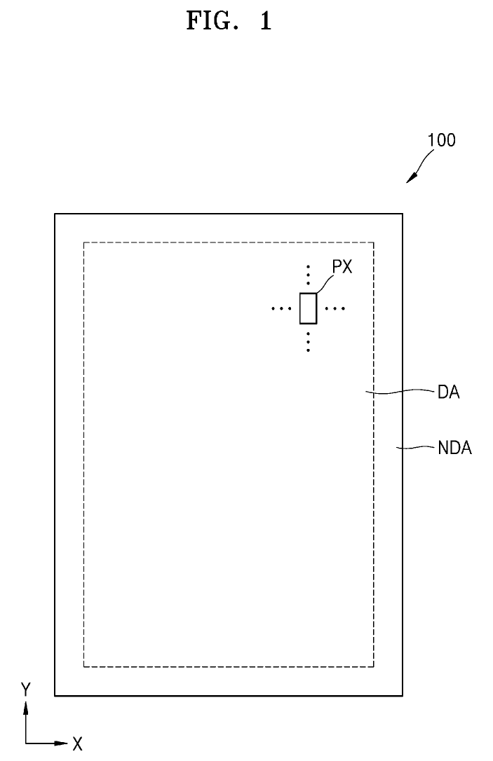

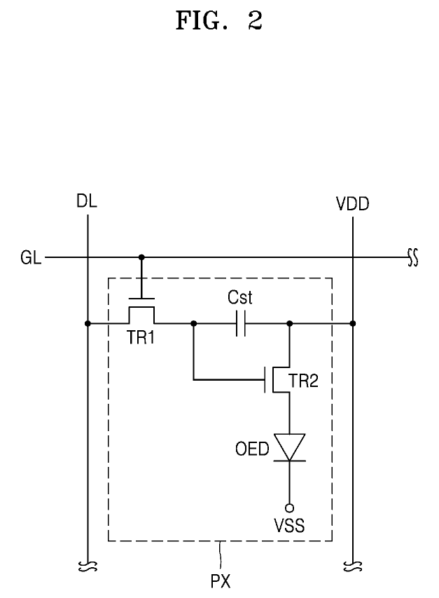

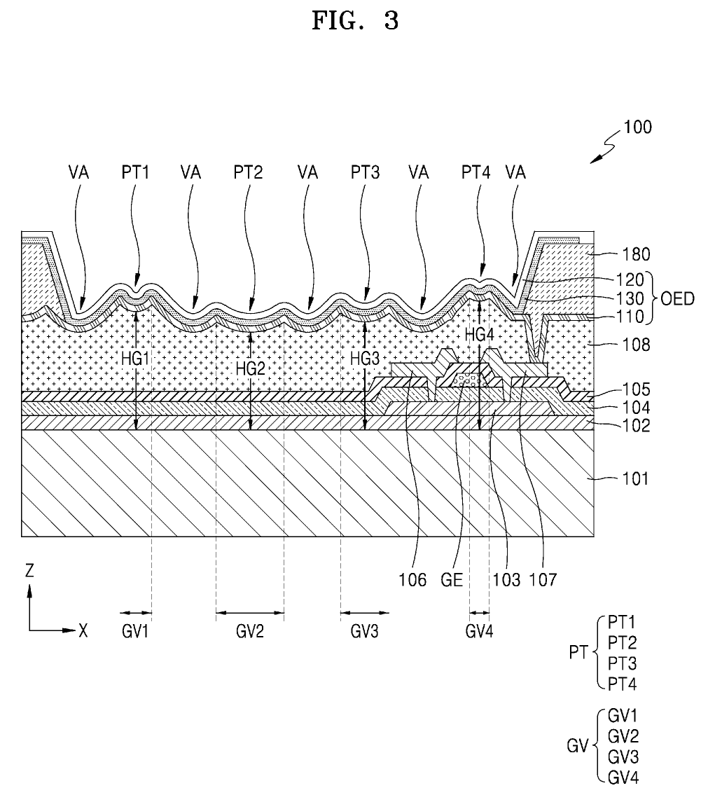

FIG. 1 is a schematic plan diagram illustrating a display device according to an embodiment of the disclosure. FIG. 2 is a schematic block diagram for a pixel of the display device of FIG. 1. FIG. 3 is a schematic cross-sectional diagram for a pixel of the display device of FIG. 1.

Referring to FIGS. 1 to 3, a display device 100 may include a substrate 101, a first electrode 110, a second electrode 120, and an intermediate layer 130.

Referring first to FIG. 1, the display device 100 may include a display area DA and a peripheral area NDA.

The display area DA may include an image-rendering region in which a plurality of pixels are arranged, each pixel including multiple sub-pixels.

The peripheral area NDA may be formed around the display area DA. The peripheral area NDA may include a non-display region. For example, the non-display region may surround the display area DA. In another example, the peripheral area NDA or the non-display region of the peripheral area NDA may be formed to be adjacent to only one or both sides of the display area DA.

In another example, the peripheral area NDA may include a drive circuit region that generates various signals for operation of the pixels of the display area DA, and the drive circuit region may include one or more drive circuits.

Referring to FIG. 2, a schematic circuit of a pixel included in the display area DA is illustrated.

For example, the circuit of FIG. 2 may illustrate the circuit of a pixel, or the circuit of one of a plurality of sub-pixels included in the single pixel.

Referring to FIG. 2, the pixel PX may be connected with wirings including a gate line GL, a data line DL, and a drive voltage line VDD.

The pixel PX may include a plurality of transistors TR1 and TR2 connected to the wirings.

The pixel PX may include an organic light-emitting diode (OLED) and a capacitor Cst connected to the plurality of transistors TR1 and TR2.

The gate line GL may extend in a direction, and the data line DL may extend in a direction intersecting the gate line GL.

The drive voltage line VDD may extend in a direction intersecting the gate line GL, and may extend in a direction parallel to the data line DL.

The gate line GL may carry a scan signal to the plurality of transistors TR1 and TR2, the data line DL may carry a data signal to the plurality of transistors TR1 and TR2, and the drive voltage line VDD may provide a drive voltage to the plurality of transistors TR1 and TR2.

The plurality of transistors TR1 and TR2 may include a first transistor TR1 and a second transistor TR2.

The first transistor TR1 may output a data signal applied to the data line DL in response to a scan signal applied to the gate line GL.

The capacitor Cst may charge a voltage corresponding to the data signal received from the first transistor TR1.

The second transistor TR2 may be connected to the organic light-emitting diode (OLED). The second transistor TR2 may control a drive current flowing through the OLED in response to the amount of charge stored in the capacitor Cst.

The OLED may emit light during the turn-on period of the second transistor TR2.

While the embodiment describes a pixel PX including two transistors TR1 and TR2, the disclosure is not limited thereto. For example, a pixel PX may include a single transistor and a capacitor, and in another example, a pixel PX may include three or more transistors and two or more capacitors.

The plurality of transistors TR1 and TR2 may have various types of configurations, and may include, for example, thin film transistors (TFTs).

The pixels of the display device will be described in more detail with reference to a cross-sectional diagram of FIG. 3 for the pixel in the display device of FIG. 1.

Referring to FIG. 3, the display device 100 may include the substrate 101 and an organic light-emitting device (OLED), wherein the OLED may include the first electrode 110, the second electrode 120, and the intermediate layer 130.

The substrate 101 may include various kinds of materials. In some embodiments, the substrate 101 may include glass, metal, or another organic material.

In another example, the substrate 101 may be formed from a flexible material. For example, the substrate 101 may be formed to bend, flex, fold, or turn readily.

In another example, the substrate 101 may include ultra-thin glass, metal, or plastic. For example, in case that plastic is used, the substrate 101 may include polyimide (PI). In another example, the substrate 101 may include at least one selected from a group including polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polycarbonate, triacetate cellulose, and cellulose acetate propionate.

The substrate 101 may have a structure of one or more layers, such as a plurality of layers. For example, the substrate 101 may include an organic layer (e.g., a resin-based material) and an inorganic layer. In another example, the substrate 101 may include a structure of an inorganic layer disposed between two organic layers.

In another example, one or more insulating layers (not illustrated) may be disposed on the substrate 101.

In an embodiment, one or more thin film transistors may be disposed on the substrate 101. For example, the second transistor TR2 of FIG. 2 may be disposed as illustrated in FIG. 3.

In another example, one or more buffer layers 102 may be disposed on the substrate 101.

The buffer layer 102 may be disposed on the substrate 101. The buffer layer 102 may function to reduce or prevent diffusion of impurities into thin film transistors to be disposed on the buffer layer 102.

The buffer layer 102 may include various kinds of materials, such as inorganic materials. In an example, the buffer layer 102 may include a silicon-based material. In another example, the buffer layer 102 may include at least one of silicon nitride (SiNₓ), silicon oxide (SiOₓ), and silicon oxynitride (SiOₓN_{y}).

In another example, the buffer layer 102 may include an oxide, and may include at least one of a metal oxide, such as aluminum oxide (AlOₓ).

In another example, the buffer layer 102 may include a multilayer structure having at least two or more stacked layers.

The buffer layer 102 may include a transistor, such as a thin film transistor, which functions as part of a circuit enabling visible light emission in the intermediate layer 130. For example, the transistor may correspond to one of the plurality of transistors TR1 and TR2 in FIG. 2, or may correspond to the second transistor TR2.

While the following illustrates a case where the thin-film transistor has a top-gate type structure with sequentially formed components such as an active layer 103, gate electrode GE, source electrode 106, and drain electrode 107, embodiments are not limited to this configuration. Various types of thin film transistors, including bottom-gate type structures, may alternatively be applied.

The active layer 103 may be formed on the buffer layer 102. The active layer 103 may include a semiconductor material, such as amorphous silicon or polycrystalline silicon. However, embodiments are not limited thereto, and the active layer 103 may include various kinds of materials. In an example, the active layer 103 may include an organic semiconductor material.

In another example, the active layer 103 may include an oxide semiconductor material. For example, the active layer 103 may include an oxide of a material selected from a Group XII, Group XIII, or Group XIV metal element such as zinc (Zn), indium (In), gallium (Ga), tin (Sn), cadmium (Cd), germanium (Ge), or hafnium (Hf), and combinations thereof.

A gate insulating layer 104 may be formed on the active layer 103. The gate insulating layer 104 may be formed as a single-layer film or a multilayer film including inorganic materials such as silicon oxide and/or silicon nitride. The gate insulating layer 104 may function to insulate the active layer 103 and the gate electrode GE.

The gate electrode GE may be formed on the gate insulating layer 104.

The gate electrode GE may be formed from a low-resistivity metallic material, for example, a single-layer film or a multilayer film of a conductive material including molybdenum (Mo), aluminum (Al), copper (Cu), titanium (Ti), or the like.

An interlayer insulating layer 105 may be formed on the gate electrode GE. The interlayer insulating layer 105 may insulate the gate electrode GE from a source electrode 106 and a drain electrode 107.

The interlayer insulating layer 105 may include a single-layer or a multilayer including an inorganic material. For example, the inorganic material may be a metal oxide or metal nitride. In an example, the inorganic material may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂).

The source electrode 106 and the drain electrode 107 may be disposed on the interlayer insulating layer 105. The source electrode 106 and the drain electrode 107 may be formed as a single-layer or a multilayer including a material having good conductivity.

The source electrode 106 and the drain electrode 107 may be electrically connected to, for example, in contact with, a region of the active layer 103.

A passivation film 108 may be disposed on the source electrode 106 and the drain electrode 107 to cover the thin film transistors.

The passivation film 108 may include an insulating material and may include a single-layer or a multilayer including for example, an organic material.

For example, the passivation film 108 may include an organic material such as polymethyl methacrylate (PMMA), a general purpose polymer such as polystyrene (PS), a polymer derivative having a phenolic group, an acrylic polymer, an imide polymer, an aryl ether polymer, an amide polymer, a fluoropolymer, a p-xylene polymer, a vinyl alcohol polymer, and blends thereof. In some embodiments, the passivation film 108 may be formed as a composite laminate of an inorganic insulating film and an organic insulating film.

An organic light emitting device (OLED) may be disposed on the passivation film 108. The OLED may include the first electrode 110, the second electrode 120, and the intermediate layer 130.

The first electrode 110 may be electrically connected to any one of the source electrode 106 and the drain electrode 107.

The first electrode 110 may have various kinds of configurations, for example, patterned into islands.

The first electrode 110 may include various kinds of conductive materials. As one example, the first electrode 110 may include at least one selected from a group including transparent conductive oxides such as indium tin oxide (ITO), indium zinc oxide (IZO), zinc oxide (ZnO), indium oxide (In₂O₃), indium gallium oxide (IGO), and aluminum zinc oxide (AZO). In some embodiments, the first electrode 110 may include a highly reflective metal, such as silver (Ag). In an example, the first electrode 110 may include a laminated structure of transparent conductive oxide (e.g., ITO) / metal (e.g., Ag) / transparent conductive oxide (e.g., ITO).

The first electrode 110 may include one or more valley portions VA and a plurality of protruding portions PT adjacent thereto. For example, each of the plurality of protruding portions PT may be positioned between the valley portions VA. In an example, the plurality of protruding portions PT may include a first protruding portion PT1, a second protruding portion PT2, a third protruding portion PT3, and a fourth protruding portion PT4 as illustrated in FIG. 3. In an example, the number of protruding portions PT may be varied.

The first protruding portion PT1 may be adjacent to the valley portion VA, and may be disposed between the valley portions VA. For example, the valley portion VA may be arranged around the periphery or around a portion of the periphery of the protruding portion PT1.

The second protruding portion PT2, the third protruding portion PT3, and the fourth protruding portion PT4 may each be adjacent to the valley portion VA, and may be disposed between the valley portion VA and the valley portion VA. For example, the valley portion VA may be arranged around the periphery or around a portion of the periphery of each of the protruding portions PT1, PT2, PT3, and PT4.

For example, a valley portion VA may be disposed between the first protruding portion PT1 and the second protruding portion PT2. For example, a valley portion VA may be disposed between the second protruding portion PT2 and the third protruding portion PT3, and the valley portion VA may be disposed between a third protruding portion PT3 and the fourth protruding portion PT4.

The plurality of protruding portions PT may include a plurality of grooves GV. For example, a groove GV may be disposed in a region including an apex (or in an apex region) of each of the plurality of protruding portions PT.

In an embodiment, a first groove GV1 may be formed on a top surface (or upper surface) of the first protruding portion PT1, e.g., in the region including the apex or in an apex region. For example, the first groove GV1 may be formed in the form of a recess in a direction opposite to the protrusion of the first protruding portion PT1. For example, the direction opposite to the protrusion of the first protruding portion PT1 may be a direction away from the substrate 101.

In an embodiment, a second groove GV2 may be formed on the top surface (or upper surface) of the second protruding portion PT2, e.g., in the region including the apex or in the apex region. For example, the second groove GV2 may be formed in the form of a recess in a direction opposite to the protrusion of the second protruding portion PT2. For example, the direction opposite to the protrusion of the second protruding portion PT2 may be a direction away from the substrate 101.

In an embodiment, a third groove GV3 may be formed on the top surface (or upper surface) of the third protruding portion PT3, e.g., in the region including the apex or in the apex region. For example, the third groove GV3 may be formed in the form of a recess in a direction opposite to the protrusion of the third protruding portion PT3. For example, the direction opposite to the protrusion of the third protruding portion PT3 may be a direction away from the substrate 101.

In an embodiment, a fourth groove GV4 may be formed on the top surface (or upper surface) of the fourth protruding portion PT4, e.g., in the region including the apex or in the apex region. For example, the fourth groove GV4 may be formed in the form of a recess in a direction opposite to the protrusion of the fourth protruding portion PT4. For example, the direction opposite to the protrusion of the fourth protruding portion PT4 may be a direction away from the substrate 101.

In another example, each of the plurality of protruding portions PT may have a hill-like shape or a mount-like shape. For example, each of the plurality of protruding portions PT may be disposed between the valley portions VA or surrounded by valley portions VA. In some embodiments, each of the plurality of grooves GV may have a crater-like shape positioned in a region including a top of each of the plurality of protruding portions PT.

In an embodiment, at least one of the plurality of grooves GV may have a different shape. For example, at least one of the plurality of grooves GV may have a different width or a different height.

For example, as illustrated in FIG. 3, the first groove GV1, the second groove GV2, the third groove GV3, and the fourth groove GV4 of the plurality of grooves GV may have different shapes. In an example, the different shapes may include different widths or different heights. Different heights and different widths of the plurality of grooves GV will be discussed below.

The first groove GV1, the second groove GV2, the third groove GV3, and the fourth groove GV4 may each have a height in a direction.

For example, the plurality of grooves GV may have heights corresponding to distances between a top surface (or upper surface) of the substrate 101 and bottom surfaces (or lower surfaces) of the plurality of grooves GV. For example, the first groove GV1 may have a first height HG1, the second groove GV2 may have a second height HG2, the third groove GV3 may have a third height HG3, and the fourth groove GV4 may have a fourth height HG4.

At least one or all of the first height HG1, the second height HG2, the third height HG3, and the fourth height HG4 may be different from each other. For example, the first height HG1, the second height HG2, the third height HG3, and the fourth height HG4 may be ordered by magnitude as follows: fourth height HG4 > first height HG1 > third height HG3 > second height HG2.

The first groove GV1, the second groove GV2, the third groove GV3, and the fourth groove GV4 may each have a width in a direction, for example, a width in a direction intersecting the height.

The first groove GV1 may have a width in a direction intersecting (or orthogonal to) the first height HG1, the second groove GV2 may have a width in a direction intersecting (or orthogonal to) the second height HG2, the third groove GV3 may have a width in a direction intersecting (or orthogonal to) the third height HG3, and the fourth groove GV4 may have a width in a direction intersecting (or orthogonal to) the fourth height HG4.

At least one, or all, of the widths of the first groove GV1, the second groove GV2, the third groove GV3, and the fourth groove GV4 may be different. For example, the widths of the first groove GV1, the second groove GV2, the third groove GV3, and the fourth groove GV4 may be ordered by magnitude as follows: width of fourth groove GV4 < width of first groove GV1 < width of third groove GV3 < width of second groove GV2.

In an embodiment, the respective widths and heights of the first groove GV1, the second groove GV2, the third groove GV3, and the fourth groove GV4 may be inversely proportional. For example, the fourth groove GV4 may have the greatest height and the smallest width, while the second groove GV2 may have the smallest height and the greatest width.

The shape of each of these grooves GV may be implemented by forming a plurality of pre-protruding portion patterns having a certain protrusion shape, and then forming differently shaped groove patterns in each apex region of the pre-protruding portion patterns.

The shape of the first electrode 110 may correspond to the passivation film 108. For example, the plurality of valley portions VA, the plurality of protruding portions PT, and the plurality of grooves GV of the first electrode 110 may be implemented according to the shape of the passivation film 108.

In an example, the passivation film 108 may include a plurality of valley portions, a plurality of protruding portions, and a plurality of grooves.

The first electrode 110 may include a plurality of valley portions VA corresponding to the plurality of valley portions of the passivation film 108, a plurality of protruding portions PT corresponding to the plurality of valley portions of the passivation film 108, and a plurality of grooves GV corresponding to the plurality of valley portions of the passivation film 108. As used herein, “corresponding” may mean that a portion is shaped to include an overlapping area and to have a protrusion or a groove in the same direction.

The second electrode 120 may be arranged to face the first electrode 110. The second electrode 120 may be formed from various kinds of conductive materials. For example, the second electrode 120 may include lithium (Li), calcium (Ca), lithium fluoride (LiF), aluminum (Al), magnesium (Mg), or silver (Ag), may be formed as a single-layer or a multilayer of at least one of the above materials, or may include an alloy material including at least two of the above materials.

The intermediate layer 130 may include an organic emission layer, and may be disposed between the first electrode 110 and the second electrode 120. The organic emission layer of the intermediate layer 130 may include a low molecular weight organic material or a high molecular weight organic material. In another example, the intermediate layer 130 may further include at least one additional layer selected from the group consisting of: a hole injection layer (HIL), a hole transport layer (HTL), an electron transport layer (ETL), and an electron injection layer (EIL), in combination with the organic emission layer.

A pixel defining film 180 may be deposited so as not to cover a predetermined region of the first electrode 110. The intermediate layer 130 may be deposited over a region of the first electrode 110 not covered by the pixel defining film 180, and the second electrode 120 may be deposited on the intermediate layer 130.

The pixel defining film 180 may be formed from various kinds of insulating materials. For example, the pixel defining film 180 may include an organic material, and may be formed by methods such as spin coating using one or more organic insulating materials selected from the group consisting of polyimide, polyamide, acrylic resin, benzocyclobutene, and phenolic resin.

In another example, the pixel defining film 180 may include a material that reduces or blocks the reflection of externally incident light, such as a black or dark colored organic material or a black pigment.

In another example not illustrated, one or more encapsulating members or films may be formed on the second electrode 120 to encapsulate the second electrode 120.

In another example, the shape of the top surface (or upper surface) of the first electrode 110 may be implemented on at least one region of the intermediate layer 130 and the second electrode 120. For example, recesses in a shape corresponding to the valley portions VA of the first electrode 110, protruding portions corresponding to the plurality of protruding portions PT, and grooves corresponding to the plurality of grooves GV may be formed on the second electrode 120.

In the display device 100 of the embodiment, the first electrode 110 may include a valley portion VA and a plurality of protruding portions PT adjacent thereto, thereby providing improved light efficiency and light extraction through optical resonance of the first electrode 110. Furthermore, the plurality of protruding portions PT may have inclined surfaces, such that the widths of the plurality of protruding portions PT decrease in a direction, for example, in a direction away from the substrate 101. This may improve a side light emission effect, thereby reducing or preventing a narrowed viewing angle of the display device 100.

In some embodiments, at least one of the plurality of protruding portions PT of the first electrode 110 in the display device 100 may have a groove GV. For example, the first electrode 110 may include a plurality of grooves GV, each of which correspond to each of the protruding portions PT. Some of the plurality of protruding portions PT may not have any groove GV.

By forming a groove GV having a depth in a direction opposite to the protrusion direction on a top surface (or upper surface), such as the apex region, of the plurality of protruding portions PT, abnormal optical properties (such as a halo or a speckle) due to reflection or diffraction of external light through the structure of the plurality of protruding portions PT may be reduced or prevented.

In an example, the plurality of grooves GV may have a depth in a direction opposite to the protrusion direction, thereby reducing the protrusion height of the protruding portion PT to reduce abnormal external light reflection.

Further, at least one of the plurality of grooves GV may have a different height, and, for example, all of the plurality of grooves GV may have different heights. This may reduce the regularity of the shape of the overall top surface (or overall upper surface) of the first electrode 110, including the plurality of protruding portions PT and grooves GV, and may facilitate increased irregularity. By mitigating the regularity of the top surface topography of the first electrode 110 to increase the irregularity, the abnormal reflection and diffraction of the external light from the first electrode 110 may be reduced. Thus, the image quality characteristics of the display device 100 may be improved.

Furthermore, in case that the display device 100 does not use a polarizing member in a region of the top surface (or upper surface) of the second electrode 120, the sensitivity to reflection by the external light may be increased, and in that case, the abnormal light effect by the external light may be reduced, thereby improving the image quality characteristics of the display device 100.

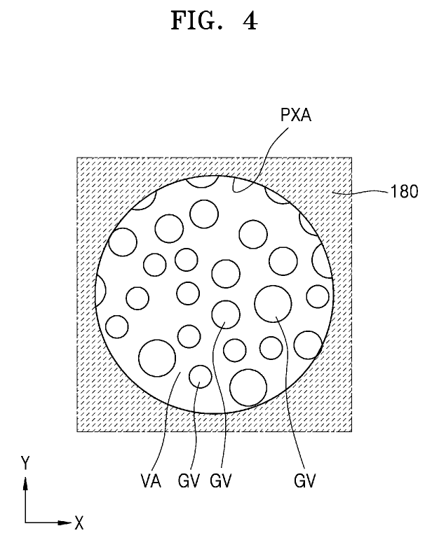

FIG. 4 is a plan diagram of a pixel of the display device of FIG. 1.

FIG. 4 is a plan diagram from a first direction of FIG. 3.

Referring to FIG. 4, a region of the pixel, such as a light extraction area PXA, is illustrated. For example, the light extraction area PXA may have curved edges or circular-like edges.

For convenience, FIG. 4 does not illustrate a plurality of protruding portions PT, but rather a plurality of grooves GV. In an example, the grooves GV may have a closed curved shape or a shape similar to a circle. In another example, the grooves GV may have a shape similar to the crater in a plan view.

As illustrated in FIG. 4, at least one of the grooves GV may have a different shape, for example, a different height or a different width. Accordingly, differently sized grooves GV may be identified when viewed from the plan diagram of FIG. 4.

Some of the plurality of protruding portions PT may have no grooves GV.

For example, the plurality of protruding portions PT may have a horn-like shape, a mountain-like shape, or a horn-like or conical shape. The plurality of protruding portions PT may have regularity. The groove GV may have a crater-like shape formed at the apex region of such a mountain-like or conical shape.

The valley portion VA may be formed adjacent to the protruding portion.

Through diverse configurations of the plurality of grooves GV, the regularity of the top surface topography (e.g., protruding portions) of the first electrode 110 may be reduced or mitigated to increase irregularity.

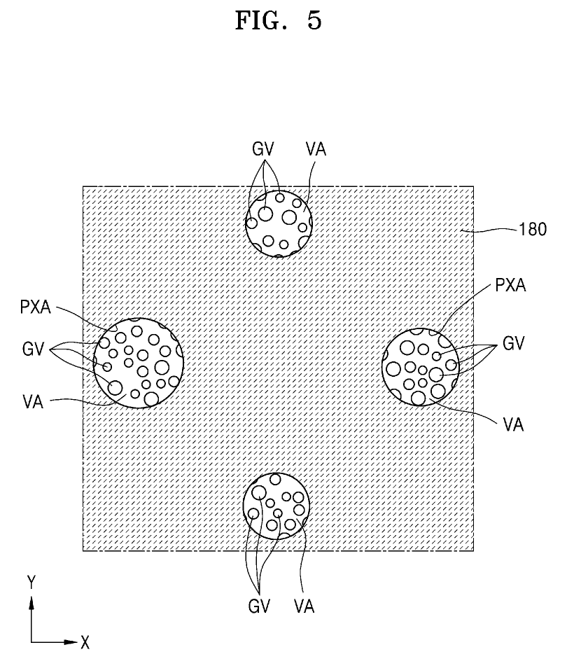

FIG. 5 is another plan diagram of a pixel of the display device of FIG. 1.

For example, FIG. 5 illustrates a region of the plurality of pixels, such as a light extraction area PXA of the plurality of pixels. For convenience, FIG. 5 does not illustrate a plurality of protruding portions PT, but illustrates a plurality of grooves GV. In an example, the grooves GV may have a closed curve shape, for example, a shape similar to a circle, or a shape similar to the crater in a plan view.

As illustrated in FIG. 5, at least one of the grooves GV may have a different shape, for example, a different height or a different width. Accordingly, differently sized grooves GV may be identified when viewed from the plan diagram of FIG. 5.

By implementing diverse configurations of the plurality of grooves GV, such as variations in size, the regularity of the top surface topography (e.g., protruding portions) of the first electrode 110 may be reduced or mitigated to increase irregularity, the irregularity of the plurality of pixels may be increased, thereby enhancing the irregularity of the plurality of pixels and improving the overall image quality characteristics of the display device 100.

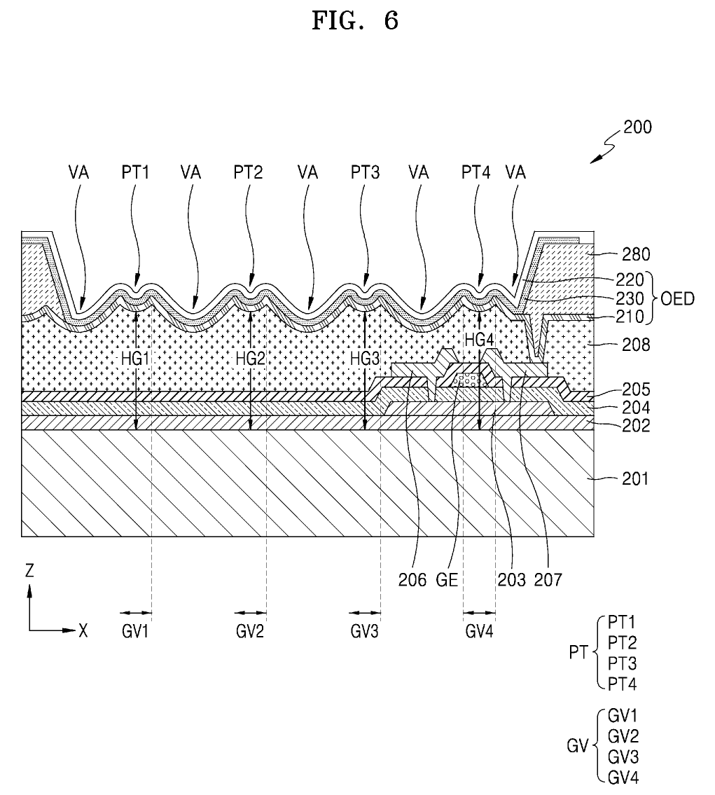

FIG. 6 is a schematic cross-sectional diagram illustrating a display device according to another embodiment of the disclosure.

Referring to FIG. 6, the display device 200 may include a substrate 201 and an organic light-emitting diode (OLED), wherein the OLED may include a first electrode 210, a second electrode 220, and an intermediate layer 230.

The substrate 201 may include various kinds of materials and may be substantially the same as described in the preceding embodiment.

In another example, one or more buffer layers 202 may be disposed on the substrate 201 and are substantially the same as described in the preceding embodiment, so a further description thereof will be omitted.

A transistor, such as a thin film transistor, may be disposed on the buffer layer 202, and the thin film transistor may include an active layer 203, a gate electrode GE, a source electrode 206, and a drain electrode 207, and is substantially the same as described in the preceding embodiment, so a further description thereof will be omitted.

A gate insulating layer 204 may be formed on the active layer 203, an interlayer insulating layer 205 may be formed on the gate electrode GE, and a passivation film 208 may be disposed on the source electrode 206 and the drain electrode 207 to cover the thin film transistor.

An organic light emitting device (OLED) may be disposed on the passivation film 208. The OLED may include a first electrode 210, a second electrode 220, and an intermediate layer 230.

The first electrode 210 may be electrically connected to any one of the source electrode 206 and the drain electrode 207.

The first electrode 210 may include one or more valley portions VA and a plurality of protruding portions PT adjacent thereto. For example, each of the plurality of protruding portions PT may be positioned between the valley portions VA. For example, the plurality of protruding portions PT may include a first protruding portion PT1, a second protruding portion PT2, a third protruding portion PT3, and a fourth protruding portion PT4 as illustrated in FIG. 6. In an example, the number of protruding portions PT may be varied.

The first protruding portion PT1 may be adjacent to the valley portion VA and may be disposed between the valley portion VA and the valley portion VA. For example, the valley portion VA may be arranged around the periphery or around a portion of the periphery of the protruding portion PT1.

The second protruding portion PT2, the third protruding portion PT3, and the fourth protruding portion PT4 may each be adjacent to the valley portion VA, and may be disposed between the valley portion VA and the valley portion VA. In an example, the valley portion VA may be arranged around the periphery or around a portion of the periphery of each of the protruding portions PT1, PT2, PT3, and PT4.

For example, a first valley portion VA may be disposed between the first protruding portion PT1 and the second protruding portion PT2, a second valley portion VA may be disposed between the second protruding portion PT2 and the third protruding portion PT3, and a third valley portion VA may be disposed between the third protruding portion PT3 and the fourth protruding portion PT4.

The plurality of protruding portions PT may include a plurality of grooves GV. For example, a groove GV may be disposed in a region including the apex (or in the apex region) of each of the plurality of protruding portions PT.

In an embodiment, a first groove GV1 may be formed on the top surface (or upper surface) of the first protruding portion PT1 in the region including the apex or in the apex region. In an example, the first groove GV1 may be formed as a recess in a direction opposite to the protrusion of the first protruding portion PT1 (e.g., in a direction away from the substrate 201).

In an embodiment, a second groove GV2 may be formed on the top surface (or upper surface) of the second protruding portion PT2 in the region including the apex or in the apex region. In an example, the second groove GV2 may be formed as a recess in a direction opposite to the protrusion of the second protruding portion PT2 (e.g., in a direction away from the substrate 201).

In an embodiment, a third groove GV3 may be formed on the top surface (or upper surface) of the third protruding portion PT3 in the region including the apex or in the apex region. For example, the third groove GV3 may be formed as a recess in a direction opposite to the protrusion of the third protruding portion PT3 (e.g., in a direction away from the substrate 201).

In an embodiment, a fourth groove GV4 may be formed on the top surface (or upper surface) of the fourth protruding portion PT4 in the region including the apex or in the apex region. In an example, the fourth groove GV4 may be formed as a recess in a direction opposite to the protrusion of the fourth protruding portion PT4 (e.g., in a direction away from the substrate 201).

In another example, each of the plurality of protruding portions PT may have a hill-like shape or a mount-like shape disposed between or surrounded by valley portions VA. In some embodiments, each of the plurality of grooves GV may have a crater-like shape positioned in a region including the top of each of the plurality of protruding portions PT.

In an embodiment, the plurality of grooves GV may each have the same shape, and for example, the plurality of grooves GV may each have the same width or the same height.

For example, as illustrated in FIG. 6, the first groove GV1, the second groove GV2, the third groove GV3, and the fourth groove GV4 of the plurality of grooves GV may all have the same shape.

In an embodiment, the first groove GV1, the second groove GV2, the third groove GV3, and the fourth groove GV4 may each have a height in a direction. For example, the plurality of grooves GV may have heights corresponding to distances between the upper surface of the substrate 201 and the bottom surfaces (or lower surfaces) of the plurality of grooves GV such that the first groove GV1 may have a first height HG1, the second groove GV2 may have a second height HG2, the third groove GV3 may have a third height HG3, and the fourth groove GV4 may have a fourth height HG4.

The first height HG1, the second height HG2, the third height HG3, and the fourth height HG4 may have the same height.

The first groove GV1, the second groove GV2, the third groove GV3, and the fourth groove GV4 may each have a same width in a direction, for example, in a direction intersecting the height.

The shape of the first electrode 210 may correspond to the passivation film 208. For example, the plurality of valley portions VA, the plurality of protruding portions PT, and the plurality of grooves GV of the first electrode 210 may be implemented according to the shape of the passivation film 208.

In an example, the passivation film 208 may include a plurality of valley portions, a plurality of protruding portions, and a plurality of grooves.

The first electrode 210 may include a plurality of valley portions VA corresponding to the valley portions of the passivation film 208, a plurality of protruding portions PT corresponding to the protruding portions of the passivation film 208, and a plurality of grooves GV corresponding to the groove of the passivation film 208. As used herein, “corresponding” may mean that a portion is shaped to include an overlapping area and have a protrusion or a groove in the same direction.

The second electrode 220 may be arranged to face the first electrode 210. The second electrode 220 may be formed from various kinds of conductive materials.

The intermediate layer 230 may include an organic emission layer, and may be disposed between the first electrode 210 and the second electrode 220.

A pixel defining film 280 may be deposited so as not to cover a predetermined region of the first electrode 210. For example, the intermediate layer 230 may be deposited over a region of the first electrode 210 not covered by the pixel defining film 280, and the second electrode 220 may be deposited on the intermediate layer 230.

In another example, one or more encapsulating members or films may be formed on the second electrode 220 to encapsulate the second electrode 220.

In another example, the shape of the top surface (or upper surface) of the first electrode 210 may be implemented on at least one region of the intermediate layer 230 and the second electrode 220. For example, recesses in a shape corresponding to the valley portions VA of the first electrode 210, protruding portions corresponding to the plurality of protruding portions PT, and grooves corresponding to the plurality of grooves GV may be formed on the second electrode 220.

In the display device 200 of the embodiment, the first electrode 210 may include a valley portion VA and a plurality of protruding portions PT adjacent thereto, thereby providing improved light efficiency and light extraction through optical resonance of the first electrode 210. Furthermore, the plurality of protruding portions PT may have inclined surfaces, such that the widths of the plurality of protruding portions PT may decrease in a direction, for example, in a direction away from the substrate 201. This may improve a side light emission effect, thereby reducing or preventing a narrowed viewing angle of the display device 200.

In some embodiments, at least one of the plurality of protruding portions PT of the first electrode 210 in the display device 200 may have a groove GV. For example, the first electrode 210 may include a plurality of grooves GV, each of which may correspond to each of the protruding portions PT. Some of the plurality of protruding portions PT may not have any groove GV.

By forming a groove GV having a depth in a direction opposite to the protrusion direction on a top surface (or upper surface), such as the apex region, of the plurality of protruding portions PT, abnormal optical properties (e.g., a halo or a speckle) due to reflection or diffraction of external light through the structure of the plurality of protruding portions PT may be reduced or prevented.

In an example, the plurality of grooves GV may have a depth in a direction opposite to the protrusion direction, thereby reducing the protrusion height of the protruding portion PT to reduce abnormal external light reflection.

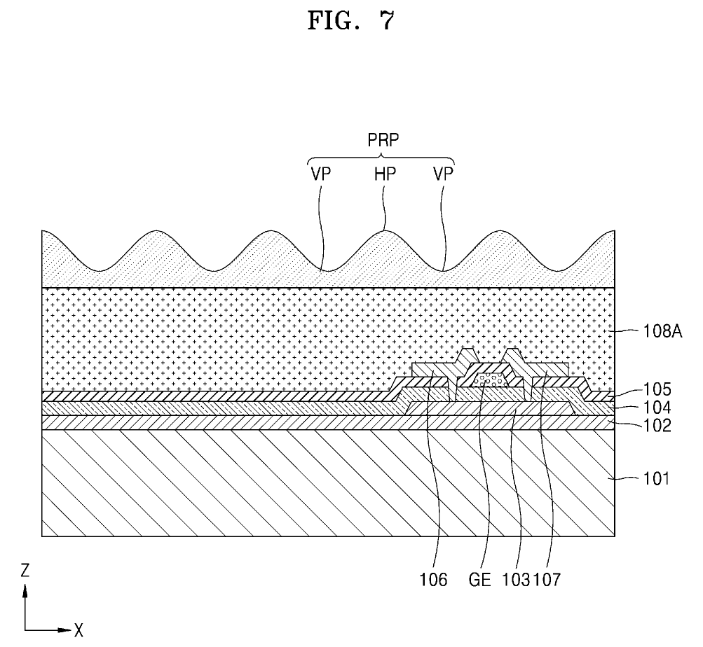

FIGS. 7 to 13 are diagrams illustrating a method of manufacturing a display device according to an embodiment of the disclosure.

For example, FIGS. 7 to 13 may illustrate a process of manufacturing the display device 100 of FIG. 1 described above for ease of description and understanding.

Referring to FIG. 7, a buffer layer 102 may be disposed on a substrate 101, and a transistor, such as a thin film transistor (TFT), may be disposed on the buffer layer 102.

An active layer 103, a gate electrode GE, a source electrode 106, and a drain electrode 107 may be disposed on the buffer layer 102.

A gate insulating layer 104 may be disposed to insulate the active layer 103 and the gate electrode GE.

An interlayer insulating layer 105 may be disposed to insulate the gate electrode GE from the source electrode 106 and the drain electrode 107.

The source electrode 106 and the drain electrode 107 may be disposed on the interlayer insulating layer 105.

A pre-passivation film 108A including a passivation film material may be disposed on the source electrode 106 and the drain electrode 107.

A patterning member PRP may be disposed on the pre-passivation film 108A. The patterning member PRP may include various kinds of materials, such as, for example, a photosensitive material. For example, the patterning member PRP may include a photoresist-based material.

The patterning member PRP may include one or more valleys VP and adjacent hills HP. The hills HP may have a convex shape that has an apex region and may narrow in size or width toward the apex region, such as a shape similar to a portion of a horn or a cone.

For example, the hill HP may have inclined surfaces. For example, each inclined surface may extend from the valley VP to the apex region of the hill HP. These inclined surfaces may have varying angles, such as 30 degrees to 70 degrees.

The patterning member PRP may allow a patterning process (e.g., a photolithography process) to be performed on the pre-passivation film 108A.

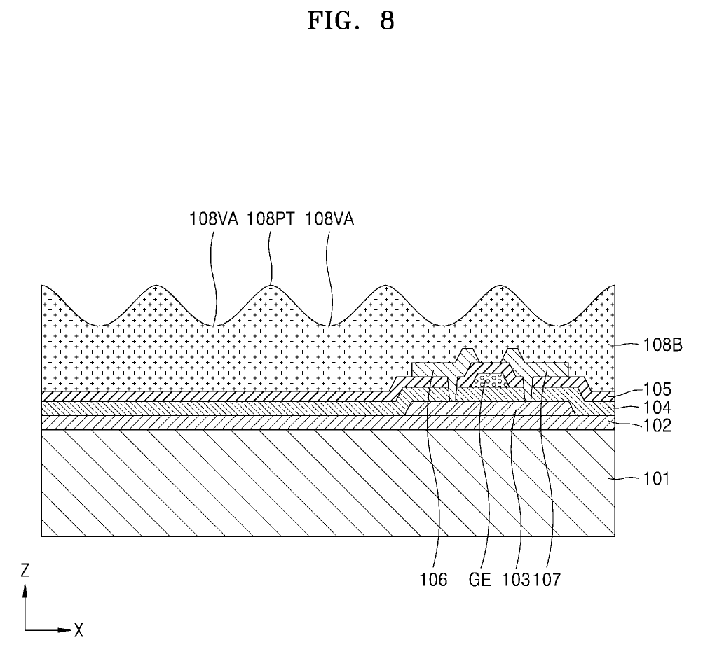

Referring to FIG. 8, it is illustrated that a patterning process on the pre-passivation film 108A is performed to form a passivation film 108B having a protruding pattern.

The patterned passivation film 108B may include a plurality of valley portions 108VA and a plurality of protruding portions 108PT adjacent thereto.

The plurality of valley portions 108VA may be disposed adjacent to the plurality of protruding portions 108PT, for example, on either side of each of the plurality of protruding portions 108PT. For example, the plurality of valley portions 108VA may be disposed around each of the plurality of protruding portions 108PT.

The plurality of protruding portions 108PT may taper in width toward the apex region thereof, and may have inclined surfaces. In an example, each of the plurality of protruding portions 108PT may have a shape similar to a portion of a horn or cone.

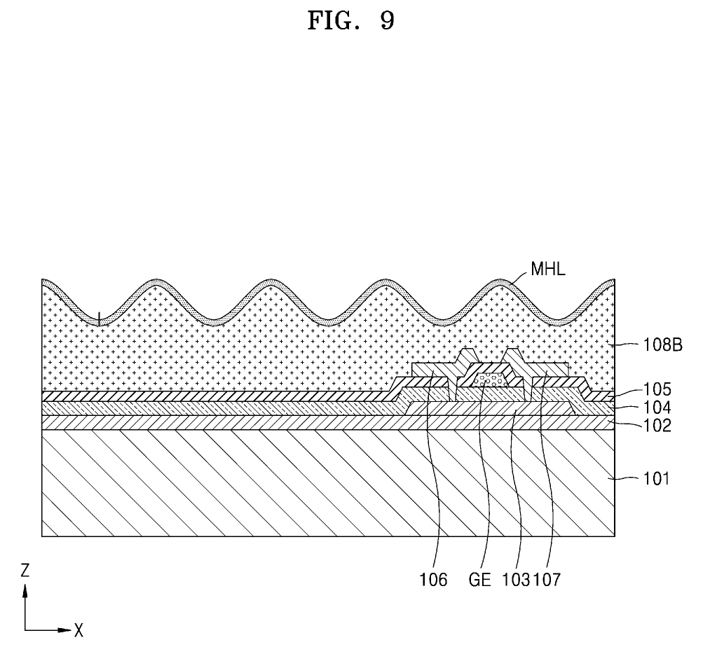

Referring to FIG. 9, a pre-masking layer MHL may be formed on the passivation film 108B having the protrusion pattern. The pre-masking layer MHL may include, for example, a material having a different etch rate than the passivation film 108B having the protrusion pattern, such as by dry etching (e.g., oxygen plasma etching), and may include, e.g., a thin film including inorganic material, metal, or conductive oxide.

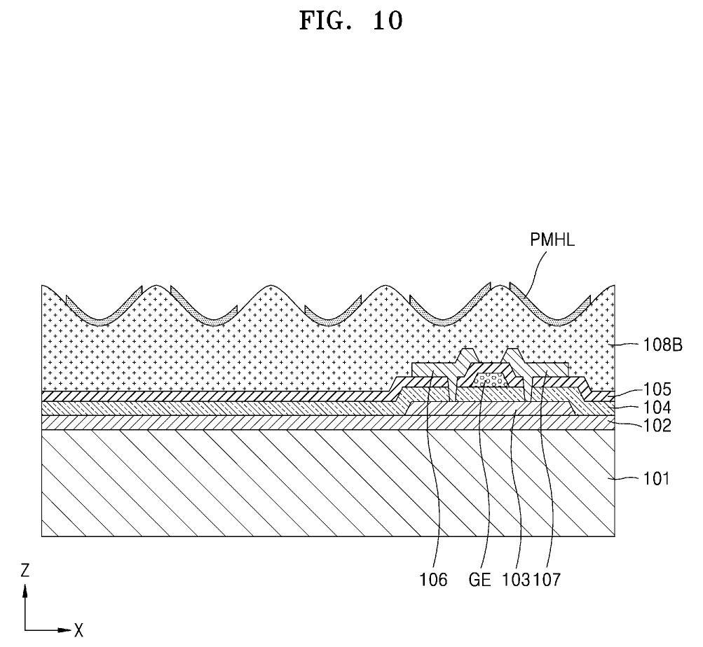

Referring to FIG. 10, apertures may be formed in some regions of the pre-masking layer MHL to form a masking member PMHL.

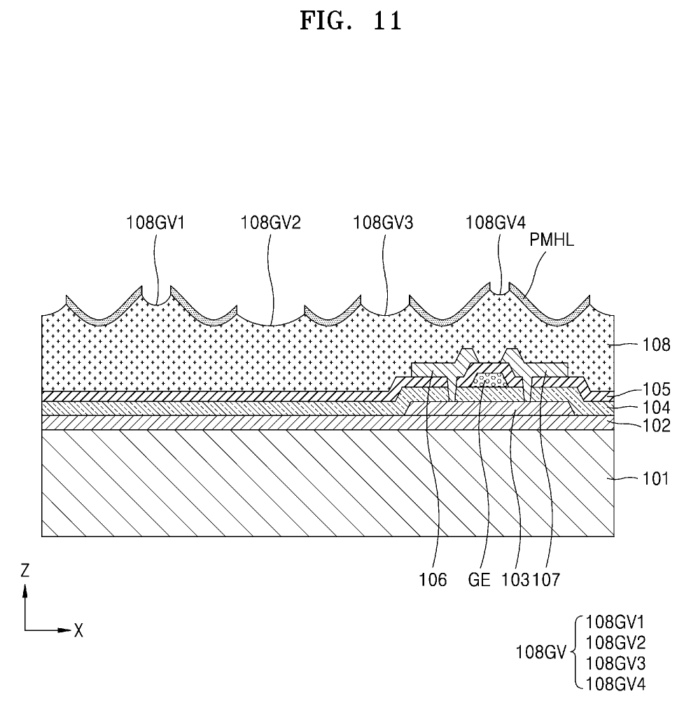

Referring to FIG. 11, an etch process may be performed on the passivation film 108B having the protrusion pattern using the masking member PMHL as an etch mask to form a passivation film 108. In an example, the etch process may include an ashing process utilizing a plasma (e.g., oxygen plasma) as a dry etch process.

Thus, the passivation film 108 may be etched in regions corresponding to the apertures of the masking member PMHL to form a plurality of passivation film grooves 108GV, such as a first passivation film groove 108GV1, a second passivation film groove 108GV2, a third passivation film groove 108GV3, and a fourth passivation film groove 108GV4.

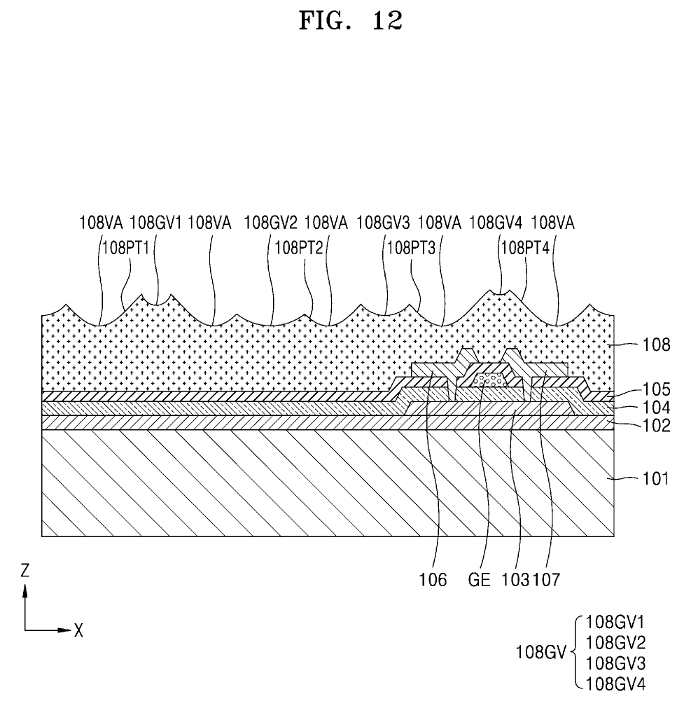

Referring to FIG. 12, the masking member PMHL may be removed.

Thus, a plurality of valley portions 108VA of the passivation film 108 may be formed such that a plurality of protruding portions (e.g., a first passivation film protruding portion 108PT1, a second passivation film protruding portion 108PT2, a third passivation film protruding portion 108PT3, and a fourth passivation film protruding portion 108PT4) may be formed.

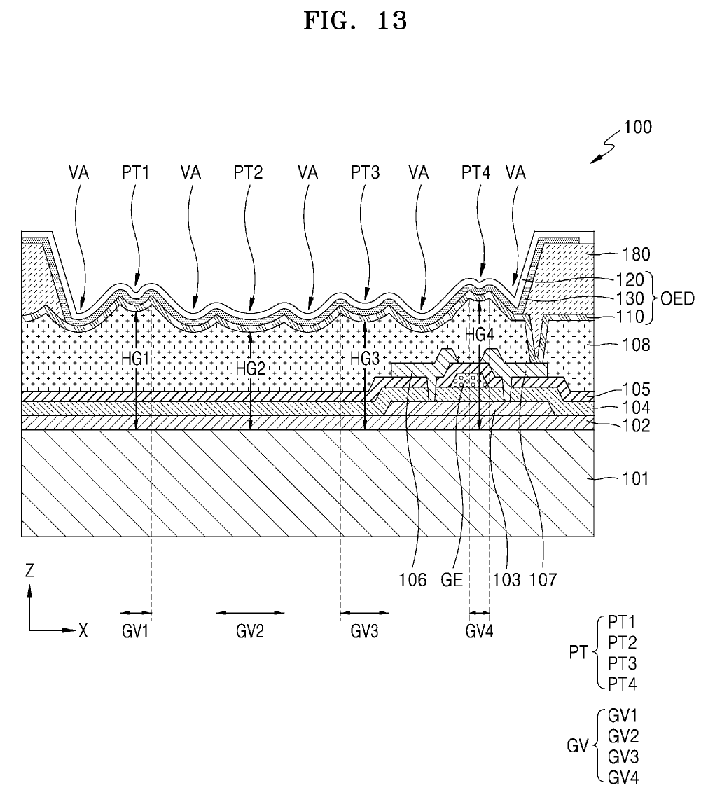

Referring to FIG. 13, a first electrode 110, an intermediate layer 130, and a second electrode 120 may be formed on the passivation film 108, thereby implementing the display device 100 of FIG. 1.

As described above, the first electrode 110 may include one or more valley portions VA and a plurality of protruding portions PT adjacent thereto. The plurality of protruding portions PT may include a plurality of grooves GV. The details of the valley portions VA, the plurality of protruding portions PT, and the plurality of grooves GV are substantially the same as described in the preceding embodiments, so a description thereof will be omitted.

According to the manufacturing method of the embodiment, the passivation film may be patterned to form protruding portions, such as a structure in which the protruding portions and valley portions are repeated many times, and then may be selectively etched through the masking member to form the grooves. The position and the size of the apertures in the masking member may be controlled. Accordingly, the valley portions, the protruding portions, and the grooves of the first electrode formed on the top surface (or upper surface) of the passivation film may be readily formed.

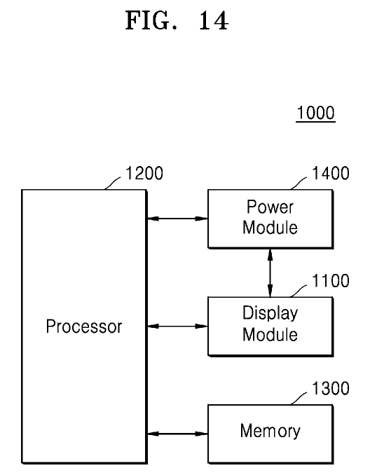

FIG. 14 is a diagram illustrating an electronic device equipped with a display device according to an embodiment of the disclosure.

The display device according to embodiments may be applied to various electronic devices. In an embodiment, the electronic device may include one or more of the display devices according to embodiments, and may optionally further include modules or devices having other additional functions in addition to the display devices.

Referring to FIG. 14, the electronic device 1000 according to an embodiment may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), and a controller.

The memory 1300 may store data information necessary for operation of the processor 1200 or the display module 1100. When the processor 1200 executes an application stored in the memory 1300, image data signals and/or input control signals may be generated and delivered to the display module 1100, and the display module 1100 may process the received signals to output image information via a display screen.

The power module 1400 may include a power supply module, such as a power adapter or a battery unit, and a power conversion module that converts power supplied by the power supply module to generate power required for operation of the electronic device 1000.

At least one of the components of the electronic device 1000 may be included within a display device according to embodiments. In some embodiments, some of the individual modules that are functionally included within one module may be included within the display device and others may be provided separately from the display device. For example, the display module 1100 may be provided within the display device, whereas the processor 1200, memory 1300, and power module 1400 may be provided as other devices within the electronic device 1000 other than the display device.

In another example, the electronic device 1000 may include the display device according to the embodiments as being included in the display module 1100.

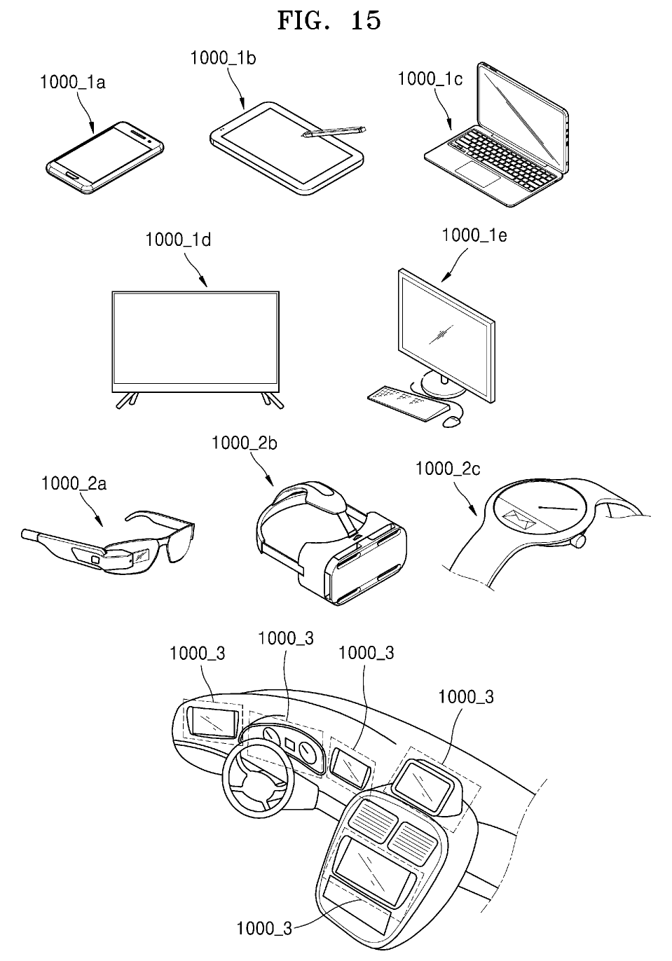

FIG. 15 is a diagram illustrating various examples of the electronic device of FIG. 14.

Referring to FIG. 15, various electronic devices with display devices according to embodiments may include image display electronic devices, such as smartphones 1000-1a, tablet personal computers 1000_1b, laptop computers 1000_1c, televisions 1000_1d, desk monitors 1000_1e, or the like.

Further, various electronic devices with display devices according to embodiments may include wearable electronic devices including display modules, such as smart glasses 1000_2a, head-mounted displays 1000_2b, smart watches 1000_2c, or the like.

Further, various electronic devices with display devices according to embodiments may include vehicle-mounted electronic devices having display modules, such as center information displays (CIDs) disposed on an instrument panel 1000_3a, a center fascia 1000_3b, a dashboard 1000_3c, and, room mirror displays 1000_3d, or the like.

The display device, the display device manufacturing method, and the electronic device according to embodiments of the disclosure may achieve improved image quality characteristics and precise control of optical properties.

While the disclosure has been described with reference to embodiments illustrated in the drawings, these are merely illustrative, and those skilled in the art will appreciate that various modifications and alternative embodiments may be derived therefrom. Accordingly, the true technical protection scope of the disclosure shall be defined by the technical spirit of the appended claims.

What is claimed is:

1. A display device comprising:
a substrate;
a first electrode on the substrate;
a second electrode facing the first electrode; and
an intermediate layer between the first electrode and the second electrode and comprising an organic emission layer,
wherein the first electrode comprises a plurality of protruding portions and one or more valley portions respectively adjacent to the plurality of protruding portions, and
wherein at least one of the plurality of protruding portions has a groove in an apex region of the at least one of the plurality of protruding portions.

2. The display device of claim 1, wherein one or more insulating layers are between the substrate and the first electrode, and
wherein the one or more insulating layers have shapes corresponding to the one or more valley portions, the plurality of protruding portions, and the groove of the first electrode.

3. The display device of claim 2, wherein each of the one or more insulating layers comprises an organic material.

4. The display device of claim 1, wherein the one or more valley portions comprise a plurality of valley portions, and
wherein at least one of the plurality of protruding portions is between the plurality of valley portions.

5. The display device of claim 1, wherein the one or more valley portions are around at least one of the plurality of protruding portions.

6. The display device of claim 1, wherein the groove comprises a plurality of grooves, and
wherein the plurality of grooves are on the plurality of protruding portions, respectively.

6. The display device of claim 1, wherein the plurality of protruding portions comprise a plurality of grooves in a plurality of apex regions the plurality of protruding portions, respectively.

7. The display device of claim 6, wherein at least one of the plurality of grooves has a different shape from another of the plurality of grooves.

8. The display device of claim 7 wherein each of the plurality of grooves has a height corresponding to a distance from the substrate, and
wherein the at least one of the plurality of grooves has a different height from at least one other one of the plurality of grooves.

9. The display device of claim 7, wherein the plurality of grooves each have a width in a direction intersecting the distance from the substrate, and
wherein the at least one of the plurality of grooves has a different width from at least one other one of the plurality of grooves.

10. The display device of claim 6, wherein positions and shapes of the plurality of grooves are irregular.

11. The display device of claim 1, wherein each of the plurality of protruding portions has an inclined surface.

12. The display device of claim 1, wherein each of the plurality of protruding portions has an area tapered toward the groove.

13. The display device of claim 1, wherein each of the plurality of protruding portions has a shape protruding from the substrate, and
wherein a lower surface of the groove has a recessed shape extending toward the substrate.

14. A method of manufacturing a display device, the method comprising:
providing a substrate;
forming a first electrode on the substrate, the first electrode comprising a plurality of protruding portions and one or more valley portions adjacent to the plurality of protruding portions;
forming a second electrode to face the first electrode; and
forming an intermediate layer between the first electrode and the second electrode,
wherein at least one of the plurality of protruding portions has a groove in an apex region of the at least one of the plurality of protruding portions.

15. The method of claim 14 further comprising:
forming one or more insulating layers between the substrate and the first electrode,
wherein the one or more insulating layers have shapes corresponding to the one or more valley portions, the plurality of protruding portions, and the groove of the first electrode.

16. The method of claim 15 wherein the forming of the one or more insulating layers comprises:
forming a plurality of protrusion patterns on the one or more insulating layers by performing a patterning process; and
forming grooves in apex regions of the plurality of protrusion patterns on the one or more insulating layers by selectively etching the one or more insulating layers using a masking member as an etch mask.

17. The method of claim 16 wherein the masking member has a plurality of apertures.

18. An electronic device comprising:
a processor configured to execute one or more applications and to generate image data; and
a display device configured to display images based on the image data, the display device comprising:
a substrate;
a first electrode on the substrate;
a second electrode facing the first electrode; and
an intermediate layer between the first electrode and the second electrode, the intermediate layer comprising an organic emission layer,
wherein the first electrode comprises a plurality of protruding portions and one or more valley portions adjacent to the plurality of protruding portions, and
wherein at least one of the plurality of protruding portions has a groove in an apex region of the at least one of the plurality of protruding portions.

19. The electronic device of claim 18 further comprising:
a memory configured to store data information for operating the processor or the display device; and
a power module configured to generate power for operating the electronic device.

20. The electronic device of claim 18, wherein the electronic device comprises an image display electronic device, a wearable electronic device, and a vehicle-mounted electronic device.
